(19) United States
(12) Patent Application Publication
(10) Pub. No.: US 2024/0383745 A1
(43) Pub. Date: Nov. 21, 2024

(54) MICROMECHANICAL COMPONENT

(71) Applicant: ROBERT BOSCH GMBH, Stuttgart (DE)

(72) Inventors: Heribert Weber, Nuertingen (DE); Peter Schmolingruber, Aidlingen (DE); Thomas Friedrich, Moessingen-Oeschingen (DE)

(21) Appl. No.: 18/692,496

(22) PCT Filed: Aug. 8, 2022
(86) PCT No.: PCT/EP2022/072246

§ 371 Date: Mar. 15, 2024

(30) Foreign Application Priority Data
Sep. 20, 2021 (DE) 10 2021 210 383.9

(51) Int. Cl. B81C 1/00; B81B 7/00

(52) U.S. Cl. CPC B81C 1/00801; B81B 7/0006; B81B 2201/0235; B81B 2201/0242; B81B 2201/0264; B81B 2203/0127; B81B 2203/04; B81C 2201/0109; B81C 2201/014

(57) ABSTRACT

A micromechanical component. The micromechanical component includes: a substrate; at least one first oxide layer arranged on the substrate; and an etch stop layer arranged directly on the at least one first oxide layer; wherein a further wiring level is arranged on a bottom side of the etch stop layer.

### FIELD

The present invention relates to a micromechanical component. The present invention also relates to a method for producing a micromechanical component.

### BACKGROUND INFORMATION

In the related art, it is conventional to separate wiring levels in a layer system from one another by electrical insulation layers.

### SUMMARY

It is an object of the present invention to provide an improved micromechanical component.

According to a first aspect of the present invention, the object may be achieved with a micromechanical component comprising:
a substrate;
at least one first oxide layer arranged directly on the substrate; and
an etch stop layer arranged directly on the at least one first oxide layer; wherein a wiring level is arranged on a bottom side of the etch stop layer.

In this way, electrical conductive paths, which are provided for an electrical connection to electrical parts and/or electrical components, such as electrodes, in a cavern region, can, for example, be guided below the etch stop layer. Advantageously, for example, slight etching of electrical insulation layers along conductive paths from the cavern region can thereby be avoided, or slight etching of electrical insulation layers of sacrificial layer material along conductive paths below the etch stop layer can thereby be avoided during the necessary etching of sacrificial layers of oxide material in a cavern region.

According to a second aspect of the present invention, the object may be achieved by a method for producing a micromechanical component, comprising the steps of:
providing a substrate;
providing at least one first oxide layer directly on the substrate;
providing a wiring level on the surface of the first oxide layer that faces away from the substrate;
providing a flat surface from regions of the wiring level and regions of the first oxide layer and/or a further oxide layer; and
providing an etch stop layer on the flat surface from regions of the wiring level and regions of the first oxide layer and/or a further oxide layer.

Preferred embodiments and developments of the micromechanical component are disclosed herein.

In an advantageous development of the micromechanical component of the present invention, the further wiring level is used to electrically contact electrical parts and/or electrical components in a cavern region. Versatile usability of the further wiring level is thereby advantageously supported.

In a further advantageous development of the micromechanical component of the present invention, at least one element of the further wiring level is arranged in a lateral etch channel. In this way, a parasitic capacitance of a conductive path of the further wiring level can advantageously be reduced, for example.

By means of the lateral etch channel, it is, for example, advantageously not necessary to provide an etch channel in a membrane in order to remove sacrificial layer material from a cavern region.

In a further advantageous development of the micromechanical component of the present invention, at least one element of the further wiring level is formed directly on a bottom side of the etch stop layer or at a distance from the etch stop layer in a self-supporting manner in a lateral etch channel.

Advantageously, various realizations of the further wiring level are thereby provided. For example, a conductive path of the further wiring level is held only by electrical contact structures, whereby a parasitic stray capacitance between the conductive path and a functional layer system arranged thereabove can be reduced.

In a further advantageous development of the micromechanical component of the present invention, a reference capacitance is formed by means of the further wiring level in combination with the etch stop layer. The reference capacitance provided thereby can advantageously be used for functionalities of the micromechanical component.

In a further advantageous development of the micromechanical component of the present invention, the further wiring level forms a reference capacitance in combination with a partially removed etch stop layer. In this way, a further alternative for providing a reference capacitance is provided by means of the further wiring level.

In a further advantageous development of the micromechanical component of the present invention, the further wiring level is formed at least partially in a planar manner within a lateral etch channel. By means of the planar further wiring level, an even better formation of a defined reference capacitance is advantageously supported.

In further advantageous developments of the micromechanical component of the present invention, the reference capacitance is arranged in an anchoring region of a cavern region and/or outside of the cavern region and/or within the cavern region. In this way, a variety of possible circuitries for using the reference capacitance formed by means of the further wiring level result for the micromechanical component.

In further advantageous developments of the micromechanical component of the present invention, the wiring level extends into a region below the cavern region. In this way, a reference capacitance produced in a defined manner can advantageously be produced from a combination of the counter electrode, the additional wiring level and the etch stop layer, wherein conductive paths for the electrical connection of the reference capacitance can also be realized by means of the wiring level.

In an advantageous development of the micromechanical component of the present invention, a thickness of the etch stop layer is formed in a defined manner in the region of the reference capacitances. In this way, the etch stop layer can be formed locally thinner or thicker as needed, whereby a size of the reference capacitance can advantageously be dimensioned.

In a further advantageous developments of the micromechanical component of the present invention, the micromechanical component is a capacitive pressure sensor and/or an acceleration sensor and/or a rotation rate sensor. Using the proposed further wiring level below the etch stop layer results in a plurality of advantageous embodiments/wiring options for the micromechanical component.

In an advantageous development of the provided method of the present invention, that depressions in the surface of the at least one first oxide layer are used by means of a CMP process to form, for example, conductive paths of the further wiring level on the top side of the at least one first oxide layer, which conductive paths are electrically insulated from one another and which, together with the at least one first oxide layer, form a flat surface.

In an advantageous development of the provided method of the present invention, the further wiring level is deposited directly on the first oxide layer, then structured, and a further oxide layer is deposited over it, wherein the further wiring level is exposed superficially by means of a planarization step.

Advantageously, no additional work for forming the further wiring level is incurred thereby. As a result, standard process sequences can advantageously be used largely unchanged to produce the proposed micromechanical component.

The present invention is described in detail below with further features and advantages with reference to a plurality of figures. Identical or functionally identical elements have the same reference signs. The figures are in particular intended to illustrate the principles essential to the present invention and are not necessarily to scale. For better clarity, it may be Substitute Specification provided that not all of the reference signs are shown in all of the figures.

### BRIEF DESCRIPTION OF THE DRAWINGS

FIG. 1 is a cross-sectional view of an example embodiment of a micromechanical component according to the present invention.

FIGS. 2A-2D, 3A-3D, and 4 show representations for methods for producing a further wiring level, according to example embodiments of the present invention.

FIG. 5-10 are cross-sectional views of further example embodiments of the micromechanical component according to the present invention.

FIG. 11 shows an equivalent circuit diagram of a Wheatstone bridge circuit, which can be realized by interconnecting membranes.

FIG. 12-15 are cross-sectional views of further example embodiments of the micromechanical component according to the present invention.

FIG. 16 shows a basic sequence for producing a micromechanical component according to an example embodiment of the present invention.

### DETAILED DESCRIPTION OF EXAMPLE EMBODIMENTS

Conventionally, during a SiO₂ sacrificial layer process, etching or slight etching of SiO₂ can occur in the region or along electrical conductive paths which are guided out of the cavern region. Since they must be guided, electrically insulated, e.g., with SiO2, within the functional layer system, e.g., in the first poly-Si layer/level, through the lateral etch boundaries of the cavern region, e.g., of poly-Si, lateral paths are produced here along conductive paths along which an etch attack on SiO₂ insulation layers can also take place during the removal of oxide sacrificial layers. The length along which SiO2 layers are removed around conductive paths is in this case dependent on the etching duration of the sacrificial layer etching process and the position of the etch channels or etch accesses in relation to conductive path passages in lateral etch boundaries of the cavern region. The closer the etch accesses and conductive path passages are to one another and the longer the sacrificial layer etching process takes, the longer slight SiO2 etchings along electrical conductive paths may be.

In principle, the insulation layers and the lateral etch boundaries of the cavern region could consist of an electrically insulating material (e.g., silicon-rich silicon nitride, SiRiN) that is etch-resistant to, for example, HF (hydrofluoric acid) in liquid or gaseous form. However, this would disadvantageously mean additional costs and more complex processing of the functional layer region.

A core concept of the present invention consists in particular in providing a further electrical wiring level, for example of doped poly-Si, which can reach into a cavern region and whose surrounding electrical insulation cannot be etch-attacked or removed during the removal of sacrificial layers from a cavern region of the component, directly on a bottom side or below a passivation or etch stop layer in a micromechanical component (e.g., an inertial sensor, a pressure sensor, a microphone, a rotation rate sensor, etc.).

In contrast, providing a further electrical wiring level under a passivation layer which is etch-resistant to a medium with which sacrificial layers are removed from a cavern region has the advantage that electrical rewirings, which allow a more complex electrical wiring of the sensor, can also be formed within the cavern region, without the electrical insulation of the further wiring level under the passivation layer being undesirably attacked or even completely removed during the sacrificial layer etching process. In this way, design and process engineering continues to support that parasitic capacitances, created by the further wiring level, to the silicon substrate can be kept small or even eliminated.

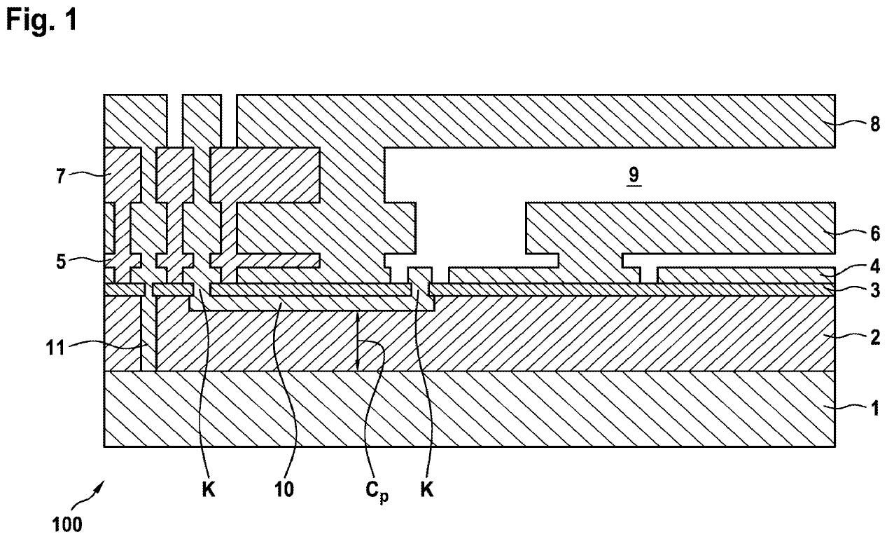

FIG. 1 is a cross-sectional view of a proposed micromechanical component 100. An etch stop layer 3 (e.g., SiRiN) can be seen, which separates the functional layer system from a substructure, which is located between the functional layer system and a silicon substrate 1. On the etch stop layer 3, the functional layer system is constructed starting with a first functional layer 4 (e.g., of doped polysilicon (poly-Si)), which serves as an electrical connection or wiring level for components of the functional layer system formed upward.

Since the etch stop layer 3 is, for example, etch-resistant to an etching medium (e.g., HF vapor), forming a further wiring level 10 of the functional layer system from, for example, doped poly-Si directly on a bottom side of the etch stop layer 3 can avoid that, during removal of, for example, a second oxide layer 5 of, for example, SiO₂ and/or a third oxide layer 7 of, for example, SiO₂ from a cavern region 9, underetchings of poly-Si conductive paths in the first functional layer 4 occur and said poly-Si conductive paths lose their adhesion to the underlying surface, and etching or slight etching of electrical insulation layers of, for example, SiO₂ occurs in the region of or along poly-Si conductive paths which are guided out of the cavern region 9.

Furthermore, the etch stop layer 3 protects the substructure with the at least one first oxide layer 2 of, for example, SiO₂ in the cavern region 9 from an etch attack by, for example, HF vapor. In this way, underetchings in the substructure of sensor components within the cavern region 9 can advantageously be avoided by providing an etch stop layer 3.

Ultimately, the proposed micromechanical component 100 of FIG. 1 is thereby formed as a capacitive pressure sensor. By means of one or more contact elements K, the wiring level 10 can be electrically connected to the functional layer structure, e.g., to electrodes in the cavern region 9.

FIG. 1 thus shows a core concept of the present invention, which in particular consists in providing the further wiring level 10 below or directly on a bottom side of the passivation or etch stop layer 3, which provides a possibility of guiding electrical connections out of the cavern region 9 via this further wiring level 10. In this way, conductive paths of the further wiring level 10 can be guided through under the lateral etch boundaries of the cavern region 9, and slight etching along conductive paths out of the cavern region 9 can be avoided. Thus, for the selection of the sacrificial layer etching time and the position of the etch accesses, this means that there are no more time and/or design limitations.

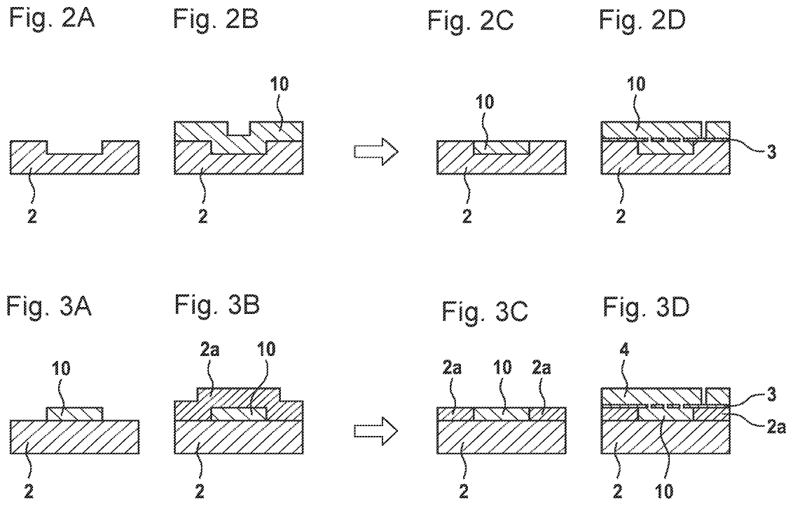

The production of the proposed further wiring level 10 can be carried out by means of convention semiconductor technology methods, as indicated in FIGS. 2A-4. In order to obtain a planar surface after the further wiring level 10 has been provided, the first oxide layer 2 is first deposited on the substrate 1 and the later structure of the further wiring level 10 is transferred by etching into the surface of the first oxide layer 2 by means of a mask.

Subsequently, the full-surface deposition of a further poly-Si layer takes place directly on the structured surface of the at least one first oxide layer 2 and then a CMP (chemical mechanical polishing) process takes place, by means of which the further poly-Si is removed from the surface of the first oxide layer 2 such that the further poly-Si remains only in depressions of the first oxide layer, as indicated in FIGS. 2A-2C. This creates a planar surface on which conductive paths of the further wiring level 10 are present, which are embedded in the at least one first oxide layer 2 or are electrically separated from one another by the at least one first oxide layer 2.

Alternatively, it is also conceivable to first deposit the at least one first oxide layer 2, to arrange the further wiring level 10 directly thereon, to completely cover said further wiring level with an additional oxide layer 2a and to planarize the surface by means of a CMP process. During planarization, the additional oxide layer 2a is removed such that the structures of the further wiring level 10 are exposed superficially, as indicated in FIGS. 3A-3C.

In both variants, the thickness of the first oxide layer 2 below the further wiring level 10 is smaller than the thickness of the oxide layer surrounding it. This can result in greater parasitic capacitances Cₚ toward the substrate 1 in the region of the further wiring level 10 than in other electrically conductive structures of the rest of the functional layer system of the micromechanical component 100.

In order to be able to minimize the parasitic capacitances Cₚ to the substrate 1, which capacitances are created during the addition of the further wiring level 10, the production of the further wiring level 10 can be carried out as follows:

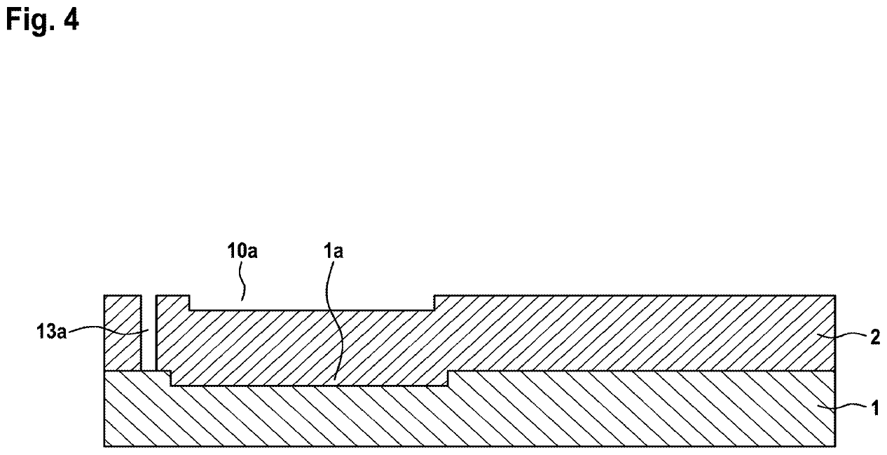

Before producing or depositing the first oxide layer 2, structures that correspond to structures in the further wiring level 10 are etched into the substrate 1 by means of a mask level. Directly onto the thus prepared surface of the substrate 1, the first oxide layer 2 is subsequently deposited, in the surface of which depressions 10a corresponding to the substrate surface form, as indicated in FIG. 4. After depositing the at least one first oxide layer 2, recesses 13a can furthermore be created in the at least one first oxide layer 2, which recesses can later be filled up with polysilicon of the further wiring level 10 and form electrical contact structures 13 by means of which electrical contacting of the substrate 1 is made possible.

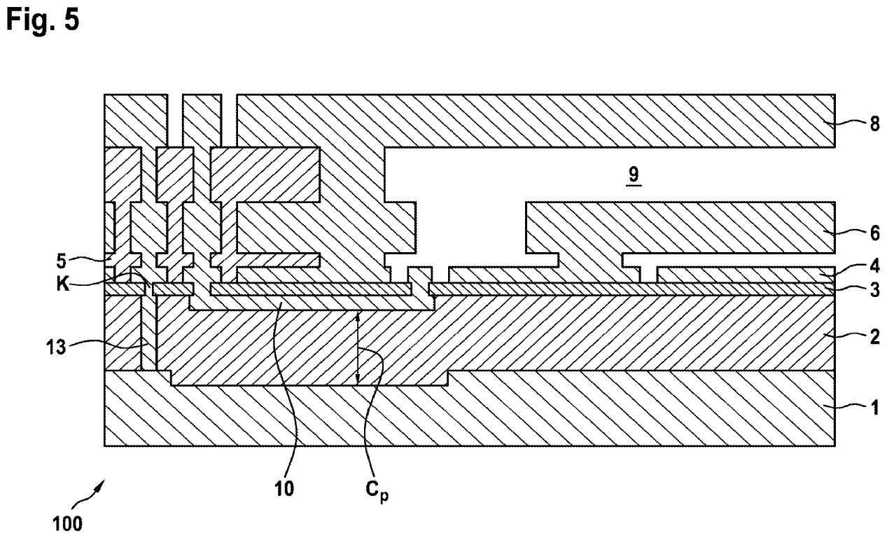

If a further doped poly-Si layer is now deposited directly onto the at least one first oxide layer 2 and the surface is planarized by means of a CMP process such that the further doped poly-Si layer on the at least one first oxide layer 2 is removed superficially and poly-Si is retained only in depressions of the first oxide layer 2, electrically conductive silicon regions that are electrically insulated from one another by the at least one first oxide layer 2 can thus be produced. In this way, it can be achieved that the thickness of the at least one first oxide layer 2 under the structures (e.g., conductive path) of the further wiring level 10 can be equal to or even greater than the thickness of the at least one first oxide layer 2 surrounding it. In this way, it can be achieved that parasitic capacitances Cₚ between structures of the further wiring level 10 and the substrate 1 can be comparable or even smaller than between electrically conductive structures of the functional layer system and the substrate 1, as shown in FIG. 5.

Alternatively, it is also conceivable to create further recesses 13a in the oxide layer 2 or, alternatively, in the oxide layer 2 and the oxide layer 2a after planarizing the surface and immediately before depositing the etch stop layer 3. During the deposition of the etch stop layer 3 of, for example, SiRiN, the further recesses 13a are filled up with material of the etch stop layer 3 and can in this way be used to produce electrically insulating lateral etch stop boundaries.

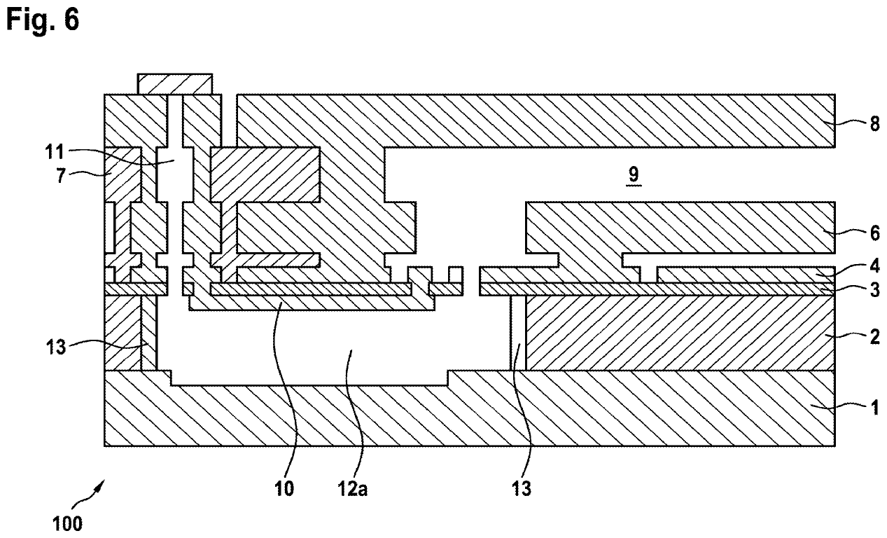

As shown in FIG. 5 and FIG. 6, the creation of the further wiring level 10 can be used to produce lateral etch stop structures for lateral etch channels 12a . . . 12n and/or electrical contact structures 13 for the substrate 1. If the further electrical wiring level 10 is produced according to one of the possibilities explained above, a further masking and etching step can take place, for example after creating depressions 1a in the substrate 1, in which further masking and etching step structures are removed from the at least one first oxide layer 2, which structures are needed to produce lateral etch stop and/or contact structures.

If a layer of poly-Si is then deposited, the structures 13 in the at least one first oxide layer 2 can be used to realize lateral etch stop structures and/or to electrically contact the substrate 1, and the recessed structures of the further wiring level 10 in the first oxide layer 2 can be filled up with silicon. If a polishing step is then carried out and the poly-Si layer is removed superficially on the at least one second oxide layer 2, a planar surface on which the mentioned Si structures are freely accessible and are separated from one another by material of the at least one first oxide layer 2 is obtained. In the variant in which no depressions for the further wiring level 10 are created in the at least one first oxide layer 2, after producing the at least one first oxide layer 2, lateral etch stop structures 13a and/or structures for electrically contacting the substrate 1 are first created in the at least one first oxide layer 2 and filled in with doped poly-Si.

The poly-Si on the surface of the at least one first oxide layer 2 can now be removed by means of a CMP method in order to subsequently be able to produce the further wiring level 10 on the planar surface thus obtained, as already described above. Optionally, however, the poly-Si can also remain on the surface of the at least one first oxide layer 2 and can be used to realize the structures for the further wiring level 10. The structures of the further wiring level 10 are then covered with an additional oxide layer 2a and exposed superficially again by means of a CMP method.

In all variants described, the deposition and structuring of the electrical insulation and etch stop layer 3 of, for example, SiRiN would now be carried out. In so doing, contact hole structures are formed by the electrical insulation and etch stop layer 3, which contact hole structures are needed for the later contacting of the further wiring level 10 and/or the contact structures 13 by the at least one first oxide layer 2 to the substrate 1, as indicated in FIGS. 2D, 3D.

In addition, openings can be formed in the etch stop layer 3, which openings serve for the targeted conduction of an etching medium from the top side of the functional layer system into a lateral etch channel 12a . . . 12n and from there into the cavern region 9.

In this case, it is also possible to integrate one or more conductive paths of the further wiring level 10 within a lateral etch channel 12a . . . 12n originating from a vertical etch channel 11. By removing the at least one first oxide layer 2 between the conductive paths and the substrate 1, parasitic capacitances Cₚ can be reduced, and regions to be provided separately for guiding conductive paths out of the cavern region 9 can be saved, as shown in FIG. 6.

In order to be able to reduce parasitic capacitances Cₚ between the further wiring level 10 and the first functional layer 4 of the functional layer system of, for example, doped poly-Si, an additional fourth oxide layer 14 (e.g., SiO₂) can be inserted after carrying out the CMP step for producing the further wiring level 10 and before depositing the etch stop layer 3. By means of this additional fourth oxide layer 14, the distance between the further wiring level 10 and the first functional layer 4 of the functional layer system can be increased, and parasitic capacitances Cₚ can be reduced.

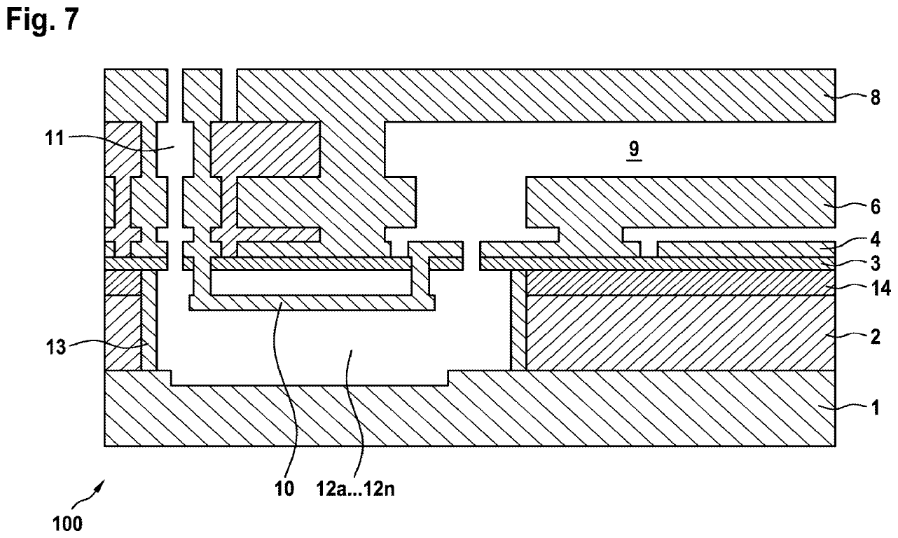

If thus buried conductive paths of the further wiring level 10 are integrated into lateral etch channels 12a . . . 12n in the substructure of the sensor element, after removing the oxide layers 2, 14 in the lateral etch channels 12a . . . 12n in the wiring level 10, released or self-supporting conductive path structures of the further wiring level 10 are produced, which advantageously can have even lower parasitic capacitances Cₚ between the further wiring level 10 and the functional layer system, as indicated in FIG. 7.

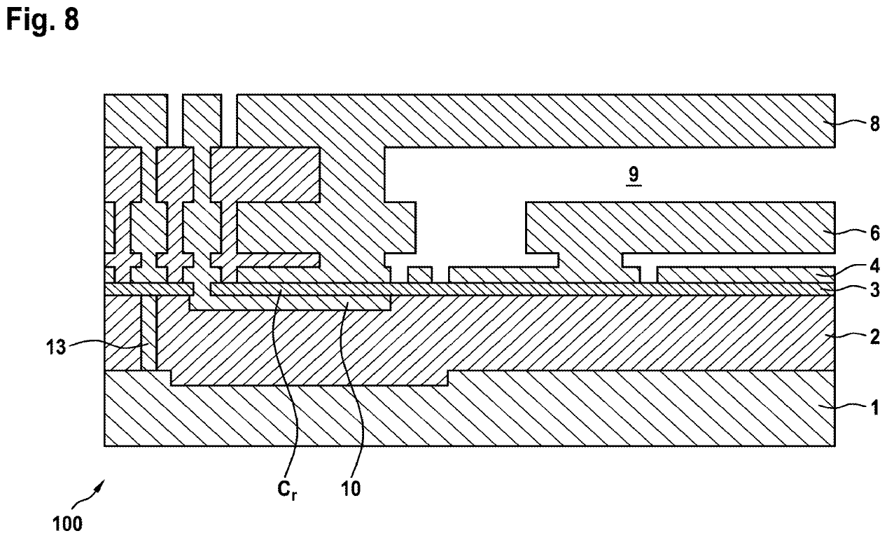

While, as explained above, parasitic capacitances between conductive paths of the further wiring level 10 and the substrate 1 and/or electrically conductive layers/conductive paths of the functional layer system can be adapted or minimized, the further wiring level 10 can also be used to, for example, produce reference capacitances Cᵣ in a targeted manner. For example, starting from the arrangement shown in FIG. 5, a reference capacitance Cᵣ, in which, for example, the etch stop layer 3 can function as a dielectric, can be created between the planar further wiring level 10 and an electrically conductive region of the functional layer system (this may, for example, be the first functional layer 4, the second functional layer 6 or the third functional layer 8), as indicated in FIG. 8.

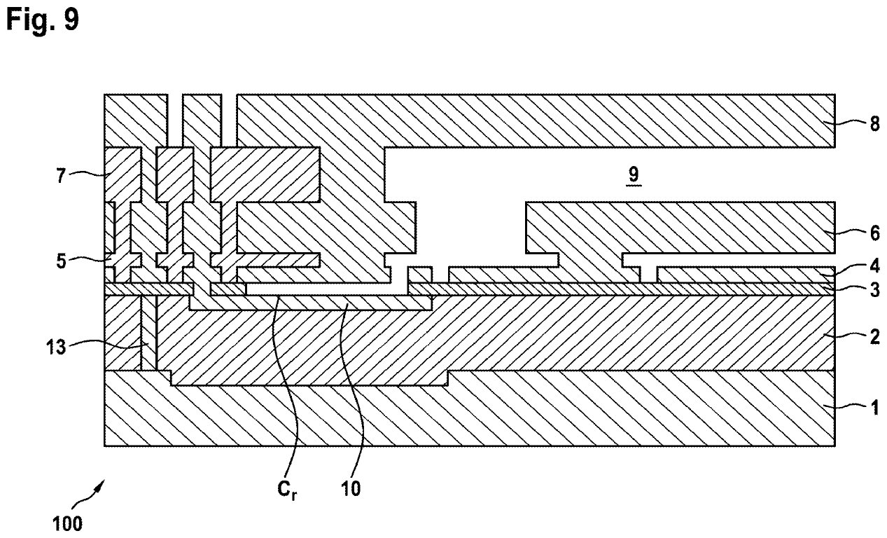

FIG. 9 shows a further variant of the proposed micromechanical component 100, in which mostly no dielectric is located between the electrodes of the reference capacitance Cᵣ. This can be achieved by also removing sacrificial layer material between the electrodes of the reference capacitance Cᵣ during the removal of the sacrificial layer material of the third oxide layer 7 (e.g., SiO2) from the cavern region 9. The etch stop layer 3 can in this case be used to realize a lateral etch stop in the reference capacitances Cᵣ.

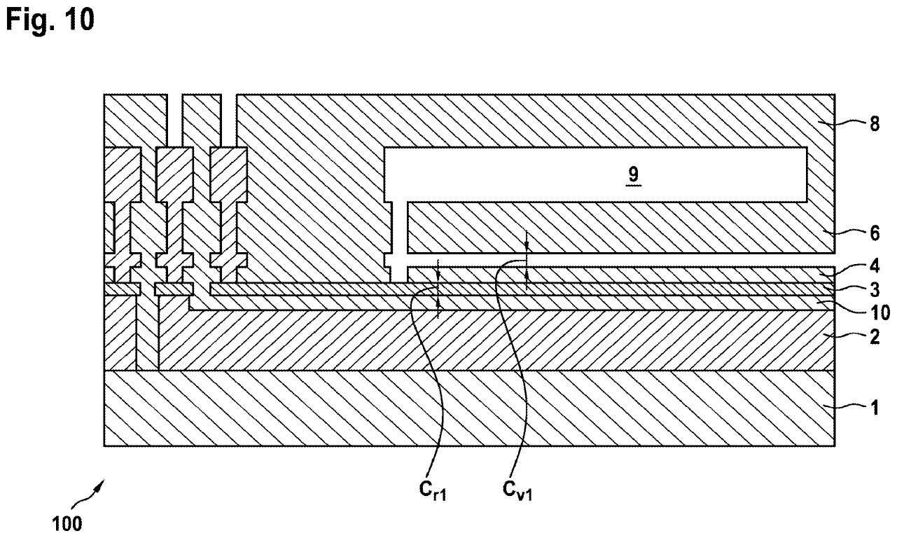

In a further variant, it is also conceivable to also form one or more reference capacitances Cᵣ₁ . . . Cᵣₙ below the counter electrode region, wherein the counter electrode can in this case serve both as an electrode for the useful capacitance and as an electrode for a reference capacitor structure. In this way, the reference capacitances Cᵣ₁ . . . Cᵣₙ can be provided below the counter electrode, as indicated in the cross-sectional view of FIG. 10. It can be seen that a movable electrode coupled to the third functional layer 8 in the form of the membrane interacts with a first functional layer 4 in the form of a fixed counter electrode arranged on the etch stop layer 3, and thereby forms a variable useful capacitance Cᵥ. The reference capacitance Cᵣ is formed from the counter electrode of the first functional layer 4, the etch stop layer 3 and the further wiring level 10.

FIG. 10 shows a further variant of the proposed micromechanical component 100, in which the further wiring level 10 formed below the etch stop layer 3 provides the possibility of using the stationary or fixed counter electrode of the variable useful capacitance Cᵥ₁ . . . Cᵥₙ for providing at least one reference capacitance Cᵣ₁ . . . Cᵣₙ formed below the counter electrode of the first functional layer 4.

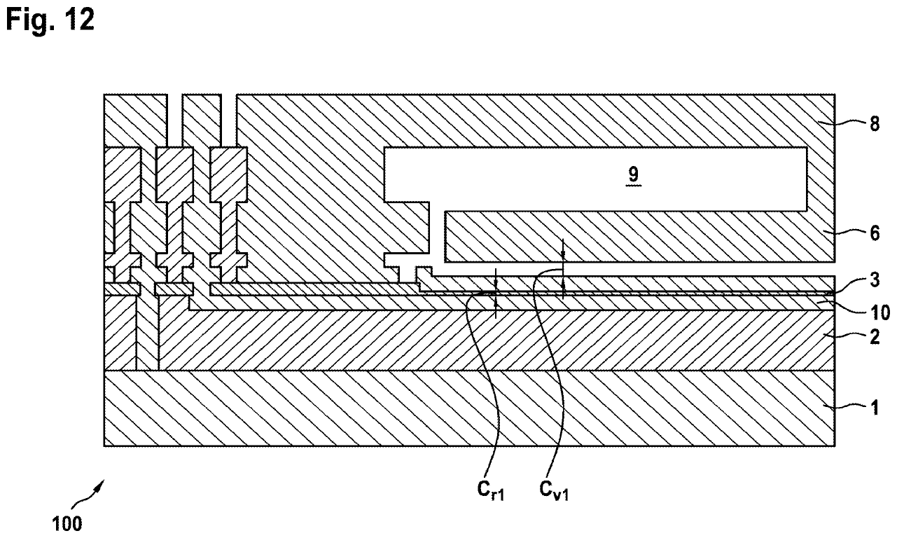

In FIG. 10, it can be seen that the etch stop layer 3 is formed as a dielectric layer between the counter electrode structure and the electrode(s) which were created by means of the further wiring level 10 or further poly-Si layer below the etch stop layer 3. By a defined reduction in the layer thickness of the etch stop layer 3 in the region of the at least one reference electrode structure, it is possible to increase the reference capacitance with the same reference electrode surface area (FIG. 12) or to reduce the reference electrode surface area with a constant reference capacitance size.

FIG. 10 thus ultimately shows that the further wiring level 10 extends into the cavern region, as a result of which the reference capacitance Cᵣ is formed substantially completely below the cavern region 9.

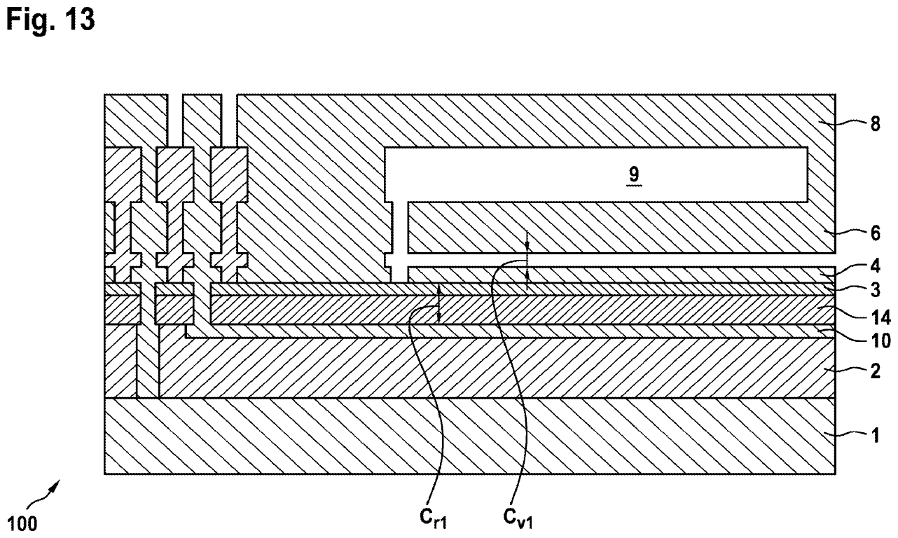

Furthermore, by providing a thicker etch stop layer 3 and/or a further dielectric layer, e.g., in the form of a fourth oxide layer 14 between the electrode surface in the further wiring level 10 and the etch stop layer 3, a smaller reference capacitance Cᵣ can be created, as indicated in principle in FIG. 13.

Optionally, it is also conceivable that the dielectric of the reference capacitance Cᵣ that is used in this case is formed from other electrically insulating layers of the functional layer system.

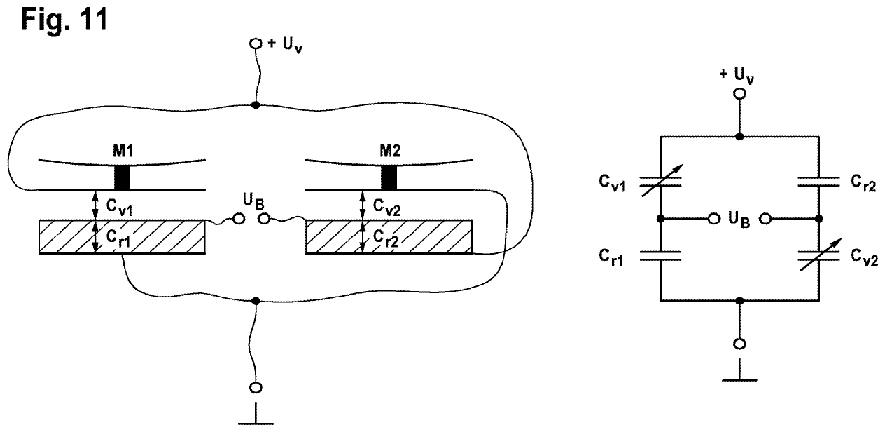

In FIG. 11, the possibility of providing a reference capacitance Cᵣ in a space-saving manner below the cavern region 9 is again shown in a simplified manner. FIG. 11 also shows how the electrical interconnection of two membrane sensors M1, M2 placed next to one another, for example two pressure sensors, with reference capacitances Cᵣ₁, Cᵣ₂ provided in the cavern region 9, can create a Wheatstone half-bridge circuit which can be produced in a simple manner with low wiring complexity.

The basic production process for implementing reference capacitances Cᵣ under a counter electrode structure is, in principle, as follows:

First, in an SiO2 layer, substrate contact and conductive path structures are created, filled up or filled in with poly-Si and optionally electrically separated from one another by means of a CMP step, for example. In this way, a planar wafer surface is obtained, onto which the further layers of the micromechanical component 100 can be deposited. Next, the deposition and structuring of the insulation or etch stop layer 3 follows, followed by the deposition and structuring of the first functional layer 4 for producing the counter electrode structure.

Subsequently, the first sacrificial oxide layer is deposited and structured, the movable electrode is created by depositing and structuring a poly-Si layer, a further second sacrificial oxide layer is deposited and structured, and finally the membrane layer is produced by depositing and structuring a poly-Si layer.

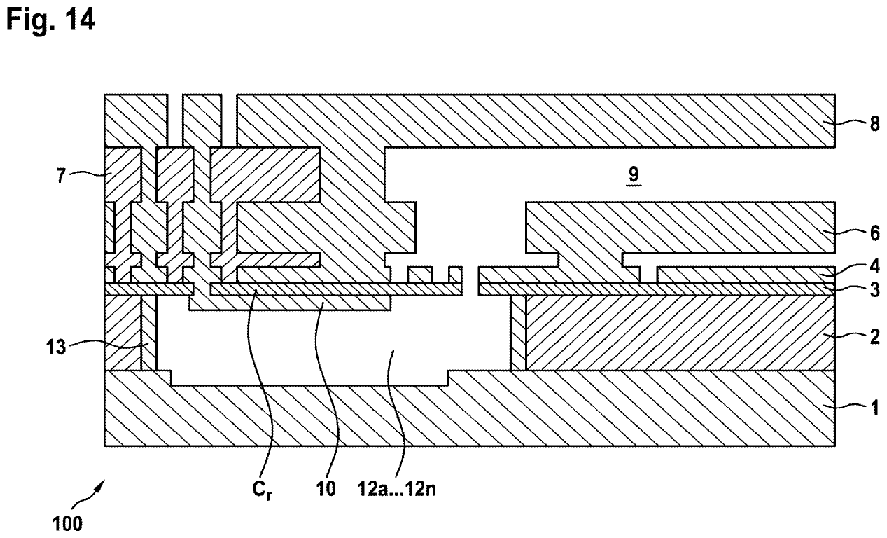

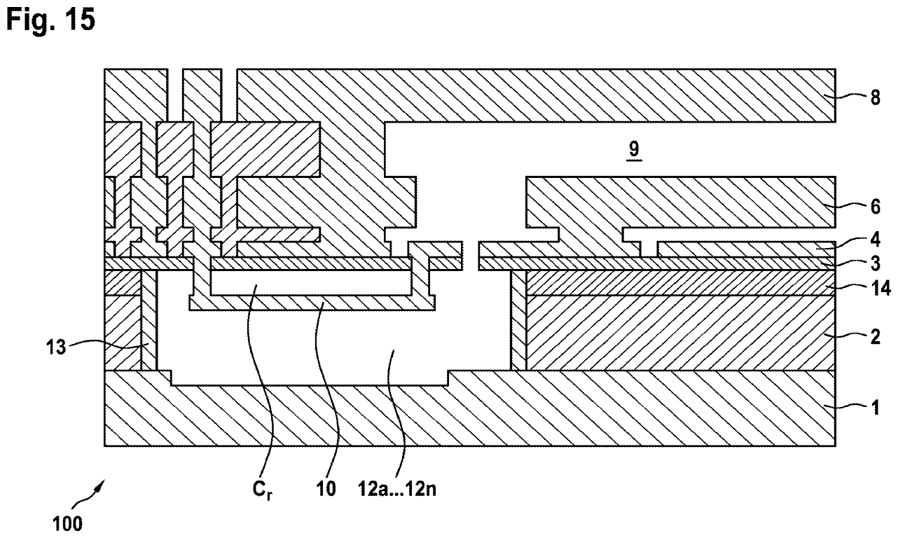

As an alternative to what was explained above, reference capacitances Cᵣ can also be provided in a targeted manner in lateral etch channel structures 12a . . . 12n, as indicated in FIG. 14. Starting from the arrangement shown in FIG. 7, self-supporting electrode surfaces can also be realized in this case if the additional fourth oxide layer 14 is also removed between the electrode surface in the further wiring level 10 and the etch stop layer 3, as indicated in FIG. 15.

In principle, a plurality of reference capacitances Cᵣ₁ . . . Cᵣₙ can also be realized in this way at any locations outside of and/or within the cavern region 9 and/or in the region of the membrane clamping or the anchoring region of the membrane.

The proposed micromechanical component 100 produced by means of the proposed method can, for example, be a capacitive pressure sensor, as explained above. Other forms of realization (not shown in figures) of the proposed micromechanical component 100, such as a microphone, piezoresistive pressure sensor, acceleration sensor, rotation rate sensor, etc., are also conceivable.

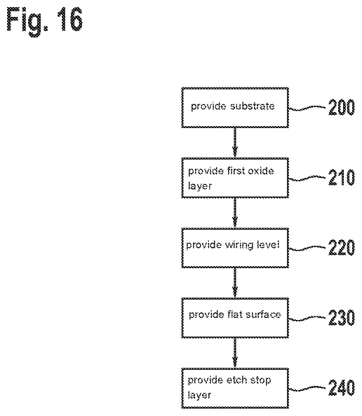

FIG. 16 shows a basic sequence of a method for producing a proposed micromechanical component 100.

In a step 200, a substrate 1 is provided.

In a step 210, a first oxide layer 2 is provided on the substrate 1.

In a step 220, a wiring level is provided on the surface of the first oxide layer 2 that faces away from the substrate.

In a step 230, a flat surface is provided from regions of the wiring level and regions of the first oxide layer and/or a further oxide layer.

In a step 240, an etch stop layer is provided on the flat surface from regions of the wiring level and regions of the first oxide layer and/or a further oxide layer.

1-15. (canceled)

16. A micromechanical component, comprising:
a substrate;
at least one first oxide layer arranged on the substrate; and
an etch stop layer arranged directly on the at least one first oxide layer; and
a further wiring level arranged on a bottom side of the etch stop layer.

17. The micromechanical component according to claim 16, wherein the further wiring level is used to electrically contact electrical parts and/or electrical components in a cavern region.

18. The micromechanical component according to claim 16, wherein an element of the further wiring level is arranged in a lateral etch channel.

19. The micromechanical component according to claim 18, wherein at least one element of the further wiring level is formed directly on a bottom side of the etch stop layer or at a distance from the etch stop layer in a self-supporting manner in a lateral etch channel.

20. The micromechanical component according to claim 16, wherein a reference capacitance is formed using the further wiring level in combination with the etch stop layer.

21. The micromechanical component according to claim 20, wherein the further wiring level in combination with a partially removed etch stop layer forms a reference capacitance.

22. The micromechanical component according to claim 16, wherein the further wiring level is formed at least partially in a planar manner within a lateral etch channel.

23. The micromechanical component according to claim 20, wherein the reference capacitance is arranged in an anchoring region of a cavern region and/or outside of the cavern region and/or within the cavern region.

24. The micromechanical component according to claim 23, wherein the wiring level extends into a region below the cavern region.

25. The micromechanical component according to claim 24, wherein a thickness of the etch stop layer in a region of the reference capacitances is formed in a defined manner.

26. The micromechanical component according to claim 16, wherein the micromechanical component is a capacitive pressure sensor and/or an acceleration sensor and/or a rotation rate sensor.

27. A method for producing a micromechanical component, comprising the following steps:
providing a substrate;
providing at least one first oxide layer directly on the substrate;
providing a wiring level on a surface of the first oxide layer that faces away from the substrate;
providing a flat surface from regions of the wiring level and regions of: (i) the first oxide layer and/or (ii) a further oxide layer; and
providing an etch stop layer on the flat surface from regions of the wiring level and regions of: (i) the first oxide layer and/or (ii) a further oxide layer.

28. The method according to claim 27, wherein, for producing the further wiring level, at least one depression is provided in the at least one first oxide layer, the depression being filled up with material of the further wiring level.

29. The method according to claim 27, wherein, after planarizing the surface and immediately before depositing the etch stop layer, further recesses are created: (i) in the oxide layer, or (ii) in the oxide layer and the further oxide layer, wherein the further recesses are filled up with material of the etch stop layer.

30. The method according to claim 27, wherein the further wiring level is deposited directly on the first oxide layer and then structured, and a further oxide layer is deposited over it, wherein the further wiring level is exposed superficially by a planarization step.
